(19) United States
(12) Patent Application Publication
(10) Pub. No.: US 2025/0306099 A1
(43) Pub. Date: Oct. 2, 2025

(54) LOGIC ANALYZER CIRCUIT, INTEGRATED CIRCUIT, AND INTEGRATED CIRCUIT SYSTEM

(71) Applicant: Mitsubishi Electric Corporation, Chiyoda-ku, Tokyo (JP)

(72) Inventors: Shu MASUDA, Chiyoda-ku, Tokyo (JP); Atsuhiro MORI, Chiyoda-ku, Tokyo (JP)

(73) Assignee: Mitsubishi Electric Corporation, Chiyoda-ku, Tokyo (JP)

(21) Appl. No.: 18/865,044

(22) PCT Filed: May 16, 2023
(86) PCT No.: PCT/JP2023/018224

§ 371 Date: Nov. 12, 2024

(30) Foreign Application Priority Data
May 17, 2022 (JP) 2022-080806

(51) Int. Cl. G01R 31/3177; G06F 11/32; G06F 11/34

(52) U.S. Cl. CPC G01R 31/3177; G06F 11/322; G06F 11/348

(57) ABSTRACT

A logic analyzer circuit includes a trace capture circuit to acquire N observation target signals from an observation target circuit when there is change in at least one of the N observation target signals and a buffer where signal data acquired by the trace capture circuit is stored. The signal data has a time stamp of an M-bit width indicating time of acquisition and state change data of an N-bit width corresponding to respective values of the N observation target signals. The signal data is data in a binary format having a fixed length of (M+N) bits.

### TECHNICAL FIELD

The present disclosure relates to an integrated circuit, and more specifically to a logic analyzer circuit to monitor a signal in the integrated circuit.

### BACKGROUND ART

As an integrated circuit has become larger in scale, an internal logic configuration thereof has become complicated and investigation into a cause in the event of a defect has become more difficult. The defect that could not be checked in simulation of logic verification occurs in a test of an actual device, and analysis thereof often becomes difficult. Therefore, there is a demand for improving efficiency of verification by selecting and monitoring a plurality of desired internal signals of the integrated circuit. Then, a monitoring circuit is implemented to provide a mechanism to acquire the desired internal signals and to output the internal signals to the outside. This monitoring circuit is called a logic analyzer circuit.

This logic analyzer circuit is provided as a circuit capable of logic synthesis without dependency on an implemented device, so that it can be implemented together with a user circuit block for verification without being dependent on an ASIC, an FPGA, or the like (see, for example, PTL 1). Both the user circuit to be monitored and the logic analyzer circuit are implemented on the integrated circuit, and state change of signals to be monitored is recorded together with a time stamp. In PTL 1, rather than continuous sampling of a value of probed signals in accordance with a system clock, only state change is sampled to reduce a data size of the acquired signal. Exemplary file formats include an encoding format using American standard code for information interchange (ASCII) such as value change dump (VCD) compliant with institute of electrical and electronics engineers (IEEE) standards. A processor capable of executing a program in the integrated circuit reads such a file, the file is converted to a waveform, and the waveform is shown in real time on a display or the like through a video output port.

### CITATION LIST

### Patent Literature

PTL 1: Japanese National Patent Publication No. 2020-529064

### SUMMARY OF INVENTION

### Technical Problem

In the VCD format shown in PTL 1, on the other hand, a time stamp value as well as an identifier and a value of signals that has changed are recorded in the ASCII format each time of state change. Therefore, in monitoring of a plurality of signals, the data size may increase in proportion to the number of changed signals per time stamp.

The present disclosure was made to solve a problem as above, and an object thereof is to provide a logic analyzer circuit, an integrated circuit, and an integrated circuit system that can achieve reduction in data size of monitor target signals.

### Solution to Problem

A logic analyzer circuit according to one disclosure includes a trace capture circuit to acquire N observation target signals from an observation target circuit when there is change in at least one of the N observation target signals, and includes a buffer where signal data acquired by the trace capture circuit is stored. The signal data has a time stamp of an M-bit width indicating time of acquisition and state change data of an N-bit width corresponding to respective values of the N observation target signals. The signal data is in a binary format having a fixed length of (M+N) bits.

### Advantageous Effects of Invention

The logic analyzer circuit, the integrated circuit, and the integrated circuit system in the present disclosure can reduce the data size of the monitor target signals.

### BRIEF DESCRIPTION OF DRAWINGS

FIG. 1 is a schematic diagram of an integrated circuit 1 based on a first embodiment.

FIG. 2 is a diagram illustrating a format of signal data stored in a buffer 105 based on the first embodiment.

FIG. 3 is a diagram illustrating an exemplary configuration of an external system 109 connected to integrated circuit 1 based on the first embodiment.

FIG. 4 is a diagram illustrating details of a signal data set stored in buffer 105 based on the first embodiment.

FIG. 5 is a diagram illustrating a conventional form of acquisition of signal data as a comparative example.

FIG. 6 is a diagram illustrating a data size in a method according to the first embodiment and a data size according to a method in the comparative example.

FIG. 7 is a schematic diagram of an integrated circuit 1 #based on a second embodiment.

FIG. 8 is a conceptual drawing of division of a plurality of signal data sets.

FIG. 9 is a flowchart illustrating processing for compressing a block in a plurality of patterns in a compression circuit 606 according to the second embodiment.

FIG. 10 is a diagram illustrating a data size in a method according to the second embodiment and a data size in the method according to the comparative example.

FIG. 11 is a diagram illustrating an internal configuration of compression circuit 606 based on a third embodiment.

FIG. 12 is a schematic diagram illustrating a method of scanning by an input data scanning unit 1101 in each block in divided signal data.

FIG. 13 is a flowchart illustrating processing for compression of each block in compression circuit 606 according to the third embodiment.

FIG. 14 is a diagram illustrating parallel processing in compression processing according to the third embodiment.

FIG. 15 is a timing chart generally showing compression code generation processing on a plurality of blocks.

FIG. 16 is a schematic diagram showing a method of processing for Huffman table update in a Huffman table update phase.

FIG. 17 shows a specific example of the Huffman table according to the third embodiment.

FIG. 18 is a diagram illustrating an integrated circuit according to another embodiment.

### DESCRIPTION OF EMBODIMENTS

An embodiment will be described below with reference to the drawings. In the description below, the same elements have the same reference characters allotted and their labels and functions are also the same. Therefore, detailed description thereof will not be repeated.

### First Embodiment

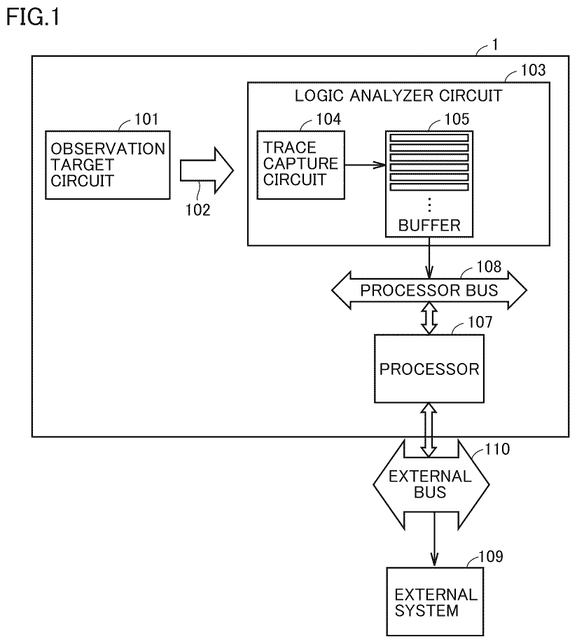

FIG. 1 is a schematic diagram of an integrated circuit 1 based on a first embodiment.

Referring to FIG. 1, integrated circuit 1 includes an observation target circuit 101, a logic analyzer circuit 103 to monitor observation target signals 102 from observation target circuit 101, a processor bus 108, and a processor 107 capable of executing a program.

Integrated circuit 1 is connected to an external system 109 through an external bus 110.

Logic analyzer circuit 103 includes a trace capture circuit 104 and a buffer 105. Trace capture circuit 104 acquires a signal when there is change in observation target signals 102. Acquired signal data is temporarily stored in buffer 105.

Processor 107 acquires through processor bus 108, signal data temporarily stored in buffer 105. Processor 107 sends the signal data to external system 109 through external bus 110.

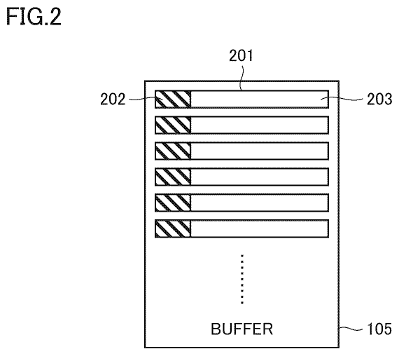

FIG. 2 is a diagram illustrating a format of signal data stored in buffer 105 based on the first embodiment.

Referring to FIG. 2, trace capture circuit 104 acquires a signal when observation target signals 102 have changed. One signal data set 201 acquired by trace capture circuit 104 is stored in buffer 105.

Signal data set 201 has a time stamp 202 located at the top and state change data 203. Time stamp 202 should only have a bit width necessary to allow time count until change of next observation target signals 102.

In the event of overflow of time stamp 202, even when there is no change in signal, time stamp 202 and state change data 203 at the time of overflow are recorded so as to clearly indicate occurrence of overflow.

A bit width necessary for accommodation of desired observation target signals should only be allocated to state change data 203.

Signal data set 201 in the present example is in a binary format having a fixed length, with time stamp 202 and state change data 203 being combined.

A plurality of pieces of signal data are stored in buffer 105 in the chronological order of signal data sets 201 from the top.

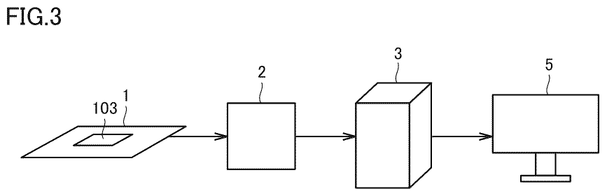

FIG. 3 is a diagram illustrating an exemplary configuration of external system 109 connected to integrated circuit 1 based on the first embodiment.

Referring to FIG. 3, external system 109 includes a debugger 2, a personal computer (PC) 3, and a display 5.

Signal data sent from integrated circuit 1 is provided to debugger 2 through external bus 110 connected to integrated circuit 1.

Debugger 2 converts a data format of the signal data to a format adapted to a bus of PC 3 and transmits the signal data to PC 3.

PC 3 is provided with software for displaying the signal data on display 5, uses the software to decode the signal data in a prescribed procedure to thereby reconstruct the signal data into a waveform, and shows the waveform on display 5.

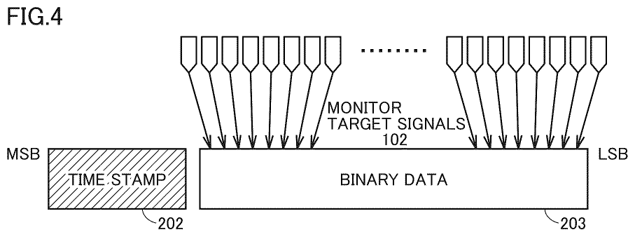

FIG. 4 is a diagram illustrating details of a signal data set stored in buffer 105 based on the first embodiment.

Referring to FIG. 4, in a data recording method based on the first embodiment, time stamp 202 indicating time of data acquisition is allocated on a side of a most significant bit (MSB). By way of example, eight bits are allocated to time stamp 202.

Then, a monitor target signals 102 composed, for example, of 120 signals is handled as binary data, with one bit being allocated to one signal, and one hundred and twenty signals are coupled from the side of the most significant bit (MSB) toward a least significant bit (LSB) to generate 120-bit state change data 203.

One piece of signal data is defined as binary data having a fixed length of 128 bits which results from coupling of 8-bit time stamp 202 and 120-bit state change data 203 to each other.

Thus, even when a value changes in a plurality of signals among monitor target signals at identical time, the signal data size always has the fixed length of 128 bits (16 bytes) and this size is never exceeded.

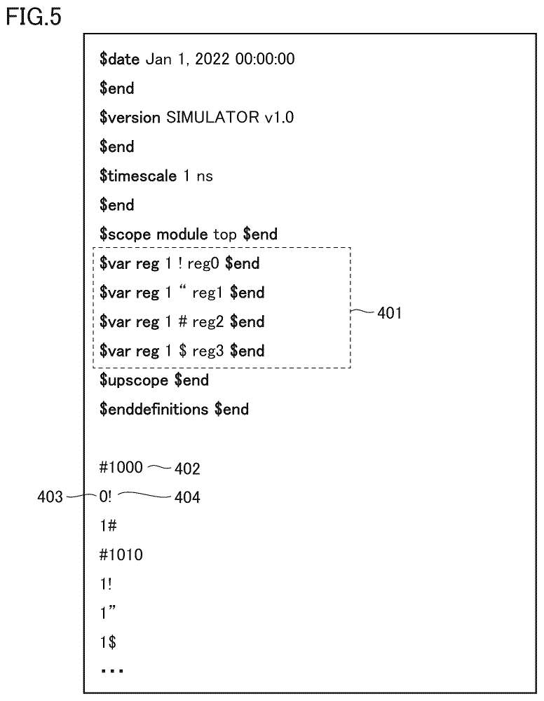

FIG. 5 is a diagram illustrating a conventional form of acquisition of signal data as a comparative example.

A form of acquisition of signal data in use of the VCD format will be described with reference to FIG. 5. In the VCD format, a definition 401 of a character string corresponding to all signals to be monitored is arranged at the top of a file.

Thereafter, as shown in FIG. 5, the form is such that, when there is change in a monitored signal, a value 403 of the signal changed in state and a corresponding signal identification character string 404 are recorded in one row for each of them, subsequently to a time stamp 402.

The data size of a time stamp having Na digits in a decimal system is calculated as 1 byte of a character at the top <#>+1 byte of a linefeed character+N_{d} bytes of the time stamp=2+N_{d} bytes.

The data size per signal that has changed is calculated as 1 byte of the value that has changed+1 byte of signal identification character string 404+1 byte of the linefeed character=3 bytes.

In this regard, the data size per time stamp in an example where there are N_{c} signals that have changed is calculated as 2+N_{d}+3×N_{c} bytes.

Therefore, the data size increases in proportion to the number of signals that have changed.

By way of example, a case where there are a large number of signals, 120 signal N_{c} for example, to be monitored is assumed.

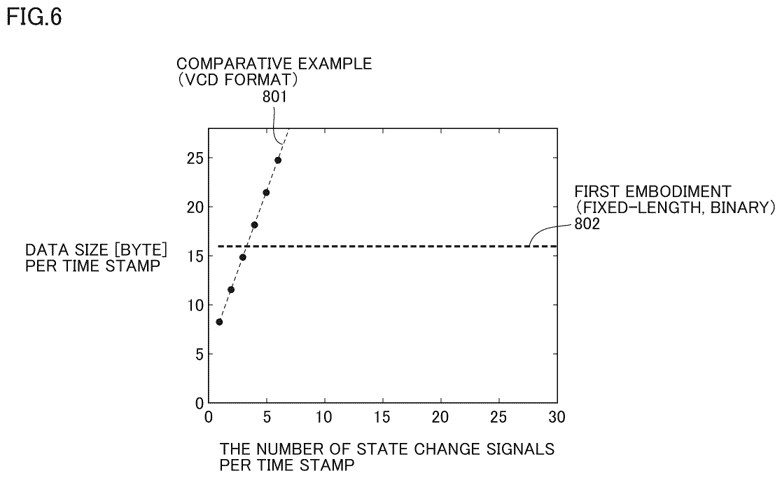

FIG. 6 is a diagram illustrating a data size in a method according to the first embodiment and a data size according to the method in the comparative example.

Referring to FIG. 6, the present example shows the data size with respect to the number of state change signals per time stamp, of the signal data in the example where the VCD format is applied.

For example, N_{d}=4 is set as the data size of the time stamp. In that case, the data size of the signal data exceeds 16 bytes when the number of signals N_{c} satisfies a condition of N_{c}>3.

On the other hand, the data size with respect to the number of state change signals per time stamp, of the signal data in the example where the binary format of the fixed length according to the first embodiment is applied is maintained constant even when the number of signals increases.

Therefore, even when there are a large number of state change signals per time stamp, the data size can significantly be reduced by applying the binary format of the fixed length as a form of transfer according to the first embodiment.

### Second Embodiment

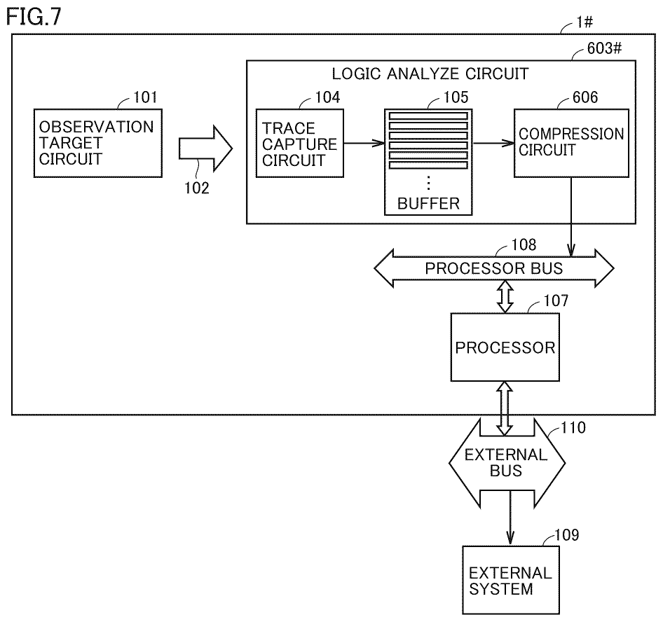

FIG. 7 is a schematic diagram of an integrated circuit 1 #based on a second embodiment.

Referring to FIG. 7, integrated circuit 1 #is different from integrated circuit 1 in replacement with a logic analyzer circuit 603 #. Since the configuration is otherwise similar to the configuration described with reference to FIG. 1, detailed description will not be repeated.

Logic analyzer circuit 603 #further includes a compression circuit 606 as compared with logic analyzer circuit 103.

Compression circuit 606 reads a data group (a plurality of signal data sets) stored in buffer 105 and compresses the data group.

Specifically, compression into a prescribed binary format in accordance with run-length encoding as a compression algorithm may be performed.

An exemplary prescribed binary format may be such a format that each value of observation target signals at the time of start of acquisition of a signal is defined as a header, followed by the number of times that signals successively have identical values in a direction of time axis each time a signal value changes. Application of this compression algorithm achieves a high compression ratio when a frequency of change in signal is low.

The data group may be divided into a plurality of blocks and the compression algorithm may be applied for each block.

In addition, blocks may be compressed in a plurality of patterns with the number of blocks resulting from division being varied, and compression pattern which achieves smallest compressed data size may be selected.

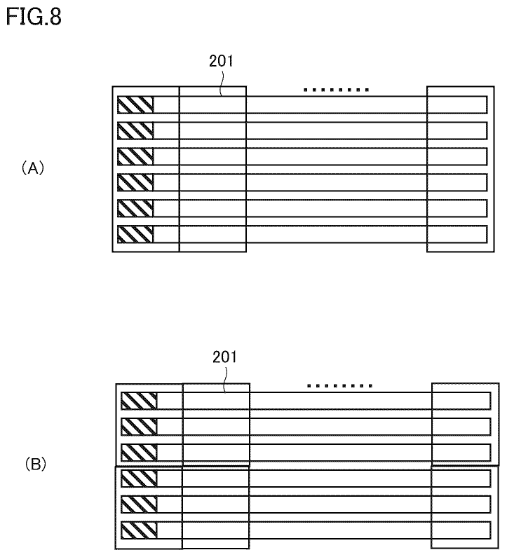

FIG. 8 is a conceptual drawing of division of a plurality of signal data sets.

FIG. 8(A) is a conceptual drawing of division in a direction of arrangement of data.

FIG. 8(B) is a conceptual drawing of further division in a direction of time of data.

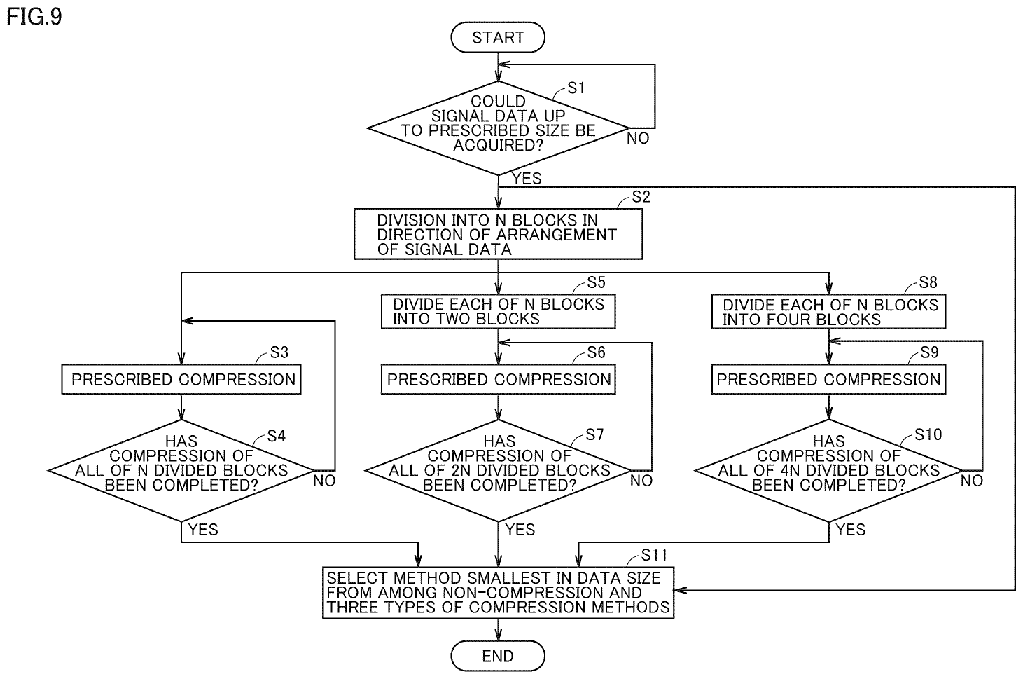

FIG. 9 is a flowchart illustrating processing for compressing a block in a plurality of patterns in compression circuit 606 according to the second embodiment.

Referring to FIG. 9, compression circuit 606 acquires signal data from buffer 105 and determines whether or not it could acquire the signal data up to a prescribed size (step S1).

Compression circuit 606 stands by until it can acquire the signal data up to the prescribed size (NO in step S1), and when it determines that it could acquire the signal data up to the prescribed size (YES in step S1), it divides the signal data set into N blocks in the direction of data arrangement of the signal data sets as described with reference to FIG. 8(A) (step S2).

Compression circuit 606 then performs prescribed compression processing on data of N divided blocks (step S3).

Compression circuit 606 then determines whether or not the compression processing on all of N divided blocks has been completed (step S4). Compression circuit 606 repeats the prescribed compression processing in step S3 until the compression processing on all of N divided blocks is completed, and when the prescribed compression processing is completed, the process proceeds to a next step.

Compression circuit 606 further divides each of N blocks into two blocks (step S5). Specifically, the compression circuit further makes division in the direction of time as described with reference to FIG. 8(B).

Compression circuit 606 then performs the prescribed compression processing on data of 2N divided blocks (step S6).

Compression circuit 606 then determines whether or not the compression processing on all of 2N divided blocks has been completed (step S7). Compression circuit 606 repeats the prescribed compression processing in step S6 until the compression processing on all of 2N divided blocks is completed, and when the prescribed compression processing is completed, the process proceeds to a next step.

Compression circuit 606 further divides each of N blocks into four blocks (step S8). Specifically, further division into two blocks in the direction of time is made with the same method as described with reference to FIG. 8(B).

Compression circuit 606 then performs the prescribed compression processing on data of 4N divided blocks (step S9).

Compression circuit 606 then determines whether or not the compression processing on all of 4N divided blocks has been completed (step S10). Compression circuit 606 repeats the prescribed compression processing in step S9 until the compression processing on all of 4N divided blocks is completed, and when the prescribed compression processing is completed, the process proceeds to a next step.

Compression circuit 606 then selects a method smallest in data size from among non-compressed data and compressed data in accordance with three types of compression methods (step S11).

Compression circuit 606 then quits the process (end).

With the method above, data compressed in accordance with the method smallest in data size among the plurality of compression patterns is selected, and selected data is sent to processor 107.

As a result of compression, even huge signal data can thus efficiently be transferred. In addition, high speed displaying of the waveform can also be achieved in real time.

Other than the run-length algorithm, a widely used lossless compression algorithm such as ZIP or GZIP may be applied as the algorithm for the prescribed compression processing, or other lossless compression algorithms readily implemented in the integrated circuit may be applied.

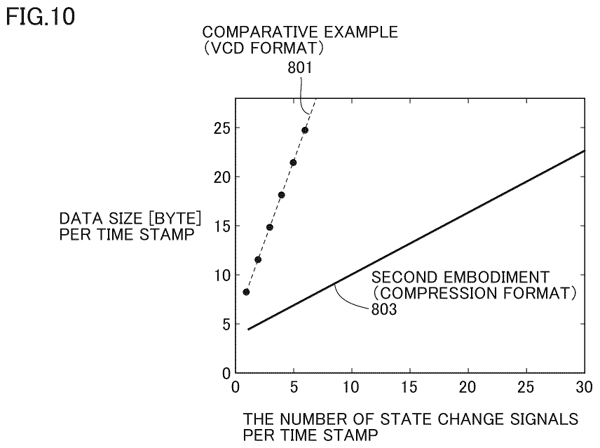

FIG. 10 is a diagram illustrating a data size in a method according to the second embodiment and a data size in a method according to the comparative example.

FIG. 10 shows a graph of a data size with respect to the number of state change signals per time stamp when compression processing is performed for each of 128 data sets with run-length encoding.

When the number of state change signals per time stamp is equal to or smaller than four, the data size can be reduced to 40% or lower, and hence the data size can be reduced as compared with the VCD format.

### Third Embodiment

An example where a Huffman code is used as the compression algorithm will be described below.

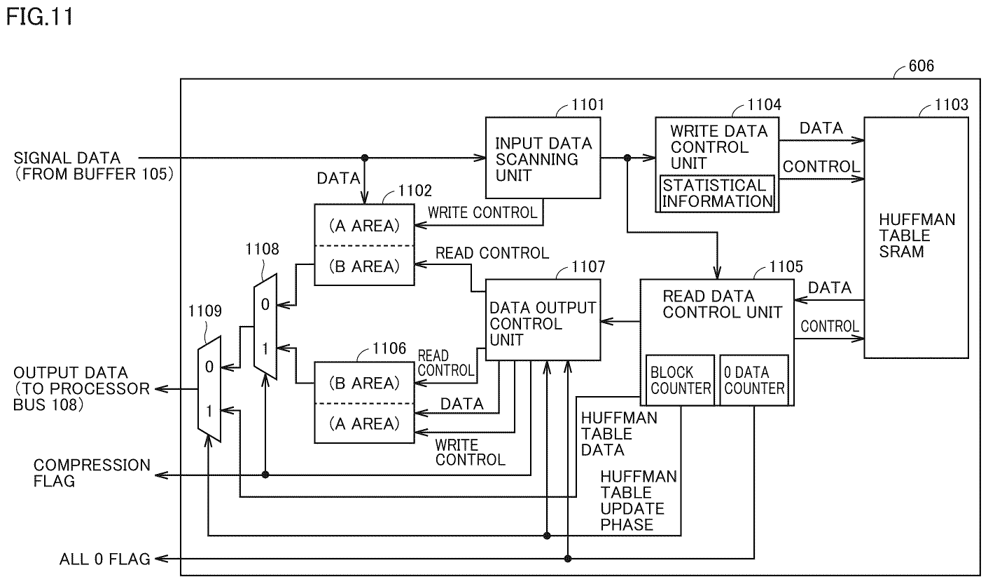

FIG. 11 is a diagram illustrating an internal configuration of compression circuit 606 based on a third embodiment.

Referring to FIG. 11, compression circuit 606 includes an input data scanning unit 1101, an original data static random access memory (SRAM) 1102, a compressed data SRAM 1106, a write data control unit 1104, a Huffman table SRAM 1103, a read data control unit 1105, a data output control unit 1107, and selectors 1108 and 1109.

Signal data from buffer 105 for one block yet to be compressed is temporarily stored in original data SRAM 1102. Original data SRAM 1102 is configured as a two-area bank configuration having an A area and a B area, and uses the bank areas as being switched in accordance with a processing pipeline stage which will be described later.

A Huffman table is stored in Huffman table SRAM 1103.

Write data control unit 1104 creates statistical information such as a decision tree, a histogram, or the like from signal data to be compressed and updates the Huffman table.

Read data control unit 1105 reads a compression code from Huffman table SRAM 1103 based on the signal data to be compressed, and in update of the Huffman table, it outputs Huffman table data to processor bus 108.

The compression code is stored in compressed data SRAM 1106. The compressed data SRAM is configured as a two-area bank configuration having an A area and a B area, and uses the bank areas as being switched in accordance with a processing pipeline stage which will be described later.

Data output control unit 1107 calculates an amount of compressed data for one block to determine output data.

Selector 1108 makes selection of data to be provided to processor bus 108 between original data SRAM 1102 and compressed data SRAM 1106.

Selector 1109 makes selection of data to be provided to processor bus 108 between output from selector 1108 and the Huffman table data.

In connection with a method of compression of signal data in compression circuit 606 based on the third embodiment, an approach to compression of data of each block when data shown in FIG. 8(A) is divided into N pieces with eight bits being defined as a unit in a division approach in the direction of data arrangement will be described.

The division method is not limited to division in units of eight bits, and division may be made with four bits, sixteen bits, or other bits being defined as a unit.

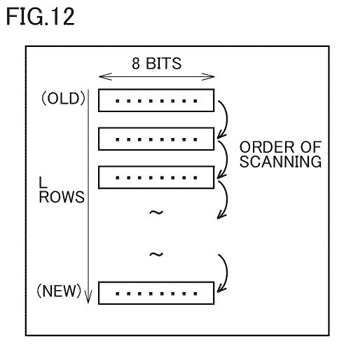

FIG. 12 is a schematic diagram illustrating a method of scanning by input data scanning unit 1101 in each block of divided signal data.

Referring to FIG. 12, each block is configured such that L rows of data of eight bits are arranged in the direction of the time axis.

Input data scanning unit 1101 sequentially takes in data in units of eight bits in a direction from top (old data) to bottom (new data) along the direction of the time axis as being split into L times, and performs the compression processing.

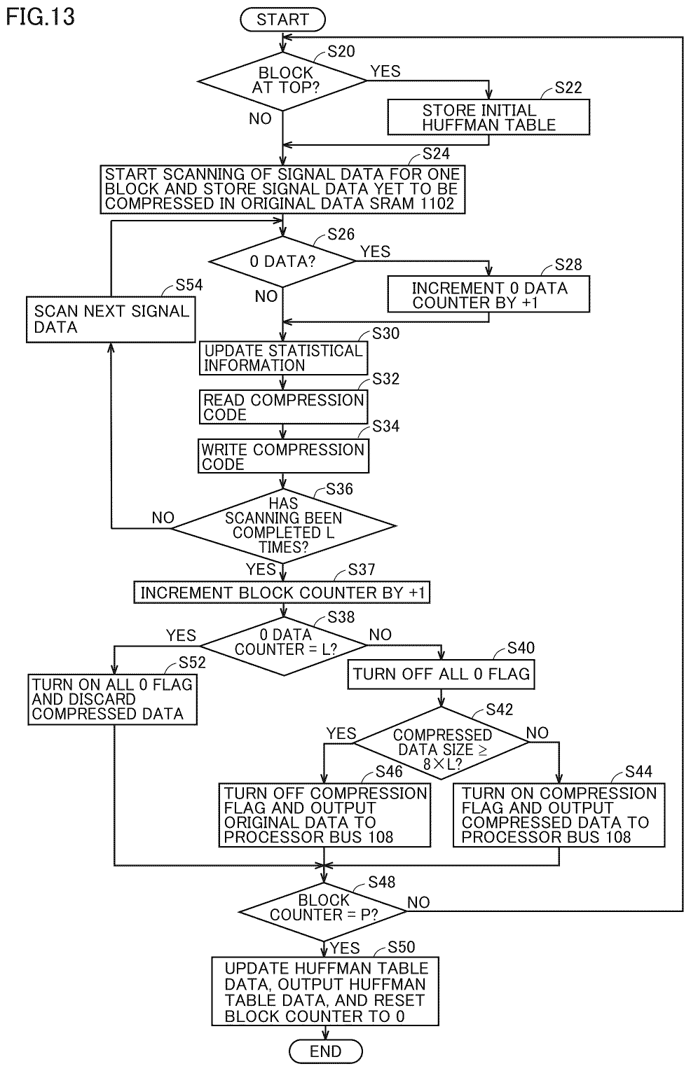

FIG. 13 is a flowchart illustrating processing for compression of each block in compression circuit 606 according to the third embodiment.

Referring to FIG. 13, in starting the compression processing, input data scanning unit 1101 determines whether or not the present block is the block at the top of data to be compressed (step S20).

When input data scanning unit 1101 then makes determination as the block at the top (YES in step S20), it instructs write data control unit 1104 to store an initial Huffman table in Huffman table SRAM 1103 (step S22).

When input data scanning unit 1101 makes determination as not being the block at the top (NO in step S20), step S22 is skipped and the process proceeds to next step S24.

In step S24, input data scanning unit 1101 starts scanning of signal data for one block and has the signal data yet to be compressed stored in original data SRAM 1102.

Input data scanning unit 1101 then determines whether or not all of eight bits of scanned data are 0 (step S26).

When input data scanning unit 1101 determines that all of eight bits are 0 (YES in step S26), read data control unit 1105 increments a 0 data counter contained therein by +1 (step S28).

When input data scanning unit 1101 determines that not all of eight bits are 0 (NO in step S26), step S28 is skipped and the process proceeds to next step S30.

Then in step S30, write data control unit 1104 updates the statistical information such as the histogram, based on the scanned 8-bit data.

Read data control unit 1105 then reads a compression code by read access to Huffman table SRAM 1103, with the scanned 8-bit data being defined as an address (step S32).

Data output control unit 1107 then writes the compression code supplied from read data control unit 1105 into compressed data SRAM 1106 as being packed therein (step S34).

Input data scanning unit 1101 then determines whether or not scanning L times, of signal data each composed of eight bits has been completed (step S36).

When input data scanning unit 1101 determines that scanning up to L times, of signal data each composed of eight bits has not been completed (NO in step S36), the process proceeds to step S54, where input data scanning unit 1101 scans next 8-bit data arrangement. The process then proceeds to step S26.

When input data scanning unit 1101 determines that scanning up to L times, of signal data each composed of eight bits has been completed (YES in step S36), it interchanges a write side and a read side of the two bank areas (A/B) of original data SRAM 1102 and compressed data SRAM 1106 and increments a block counter contained in read data control unit 1105 by +1 (step S37).

Read data control unit 1105 then determines whether or not the value of the 0 data counter contained therein is equal to L (step S38).

When read data control unit 1105 determines that the value of the 0 data counter contained therein is equal to L (YES in step S38), it turns an all-0 flag to ON (“1”).

Read data control unit 1105 then instructs data output control unit 1107 to discard compressed data for one block stored in compressed data SRAM 1106 (step S52). The process then proceeds to next step S48.

When read data control unit 1105 determines that the value of the 0 data counter contained therein is not equal to L (NO in step S38), on the other hand, it turns the all-0 flag to OFF (“0”) (step S40).

Data output control unit 1107 then determines whether or not the size of the compressed data for one block stored in compressed data SRAM 1106 is equal to or larger than the size (8×L bits) of the signal data yet to be compressed (step S42).

When the size of the compressed data for one block is equal to or larger than the size of the signal data yet to be compressed (YES in step S42), data output control unit 1107 sets a compression flag to OFF (“0”). Accordingly, data on the side of original data SRAM 1102 is selected in accordance with selector 1108 and provided to processor bus 108 (step S46).

When the size of the compressed data for one block is smaller than the size (8×L bits) of the signal data yet to be compressed (NO in step S42), data output control unit 1107 sets the compression flag to ON (“1”). Accordingly, data on the side of compressed data SRAM 1106 is selected in accordance with selector 1108 and provided to processor bus 108 (step S44).

Read data control unit 1105 then determines whether or not the value of the block counter contained therein has reached P (step S48). By way of example, in the case of division into N with eight bits being defined as the unit, P is set to P=N.

When read data control unit 1105 determines that the value of the block counter has reached P (YES in step S48), write data control unit 1104 updates Huffman table information stored in Huffman table SRAM 1103 based on the statistical information such as the calculated histogram, outputs the Huffman table data to processor bus 108 through selector 1109, and resets the block counter to 0 (step S50).

When the value of the block counter has not reached P (NO in step S48), on the other hand, the process returns to step S20 and the processing above is repeated. The compression processing is thus repeatedly performed for each one block.

In the present example, though division into N with 8-bit data arrangement being defined as the unit is described by way of example, without being limited as such, division of N blocks into two or four blocks is also similarly applicable.

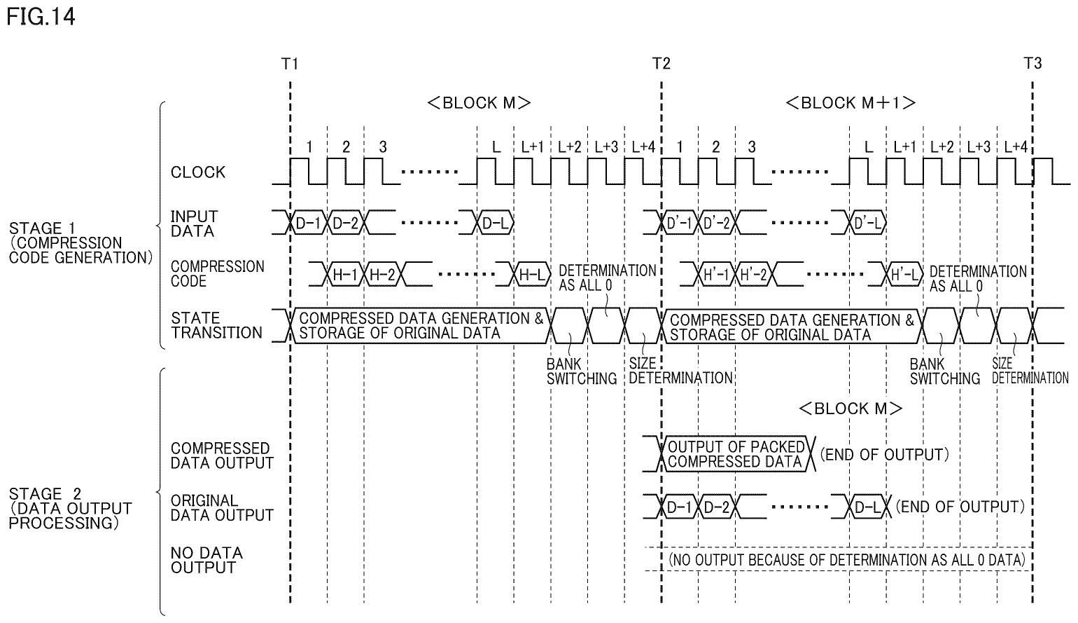

FIG. 14 is a diagram illustrating parallel processing in compression processing according to the third embodiment.

FIG. 14 shows division into two pipeline stages for a higher speed. Specifically, a timing chart of processing of successive blocks in parallel is shown.

Specifically, compression code generation processing and data output processing are performed separately in parallel are shown.

For a first processing time period (between time T1 and time T2), compression code generation processing in a stage 1 is performed on an Mth block.

Initially, in conformity with a clock cycle, L (L corresponding to the number of rows to be scanned shown in FIG. 12) pieces of 8-bit data from signal data D-1 to signal data D-L are provided.

By reading from Huffman table SRAM 1103 with this data being defined as the address, compression codes H-1 to H-L are read one cycle later.

Reading of the last compression code is completed in an L+1th cycle in a phase M.

In a next cycle (an L+2th cycle), switching between the banks is made, in a next cycle (an L+3th cycle), all 0 determination is made, and in a further next cycle (an L+4th cycle), the size of the compressed data is determined.

As set forth above, the number of cycles required for compression code generation processing is L+4 cycles.

In a next processing time period (between time T2 and time T3), the compression code generation processing in stage 1 is performed on an M+1th block and data output processing in a stage 2 is performed on the Mth block.

In stage 2, during the L+4 cycles, processing for providing compressed data or original data to processor bus 108 or providing no data as a result of all 0 determination is performed based on a result of determination.

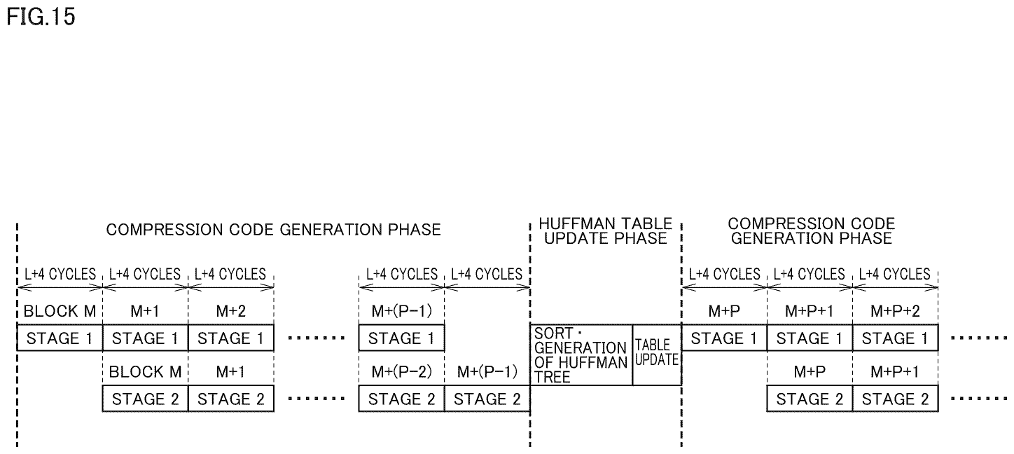

FIG. 15 is a timing chart generally showing the compression code generation processing on a plurality of blocks.

FIG. 15 shows entry in a Huffman table update phase after the compression code generation processing in stage 1 and the data output processing in stage 2 are performed on the Mth block to an M+(P−1)th block (that is, P blocks).

The information in the Huffman table is updated, and output to processor bus 108 is provided. When the Huffman table update phase ends, the compression code generation processing in stage 1 and the data output processing in stage 2 are repeated on an M+Pth block to an M+(2P−1)th block (that is, P blocks).

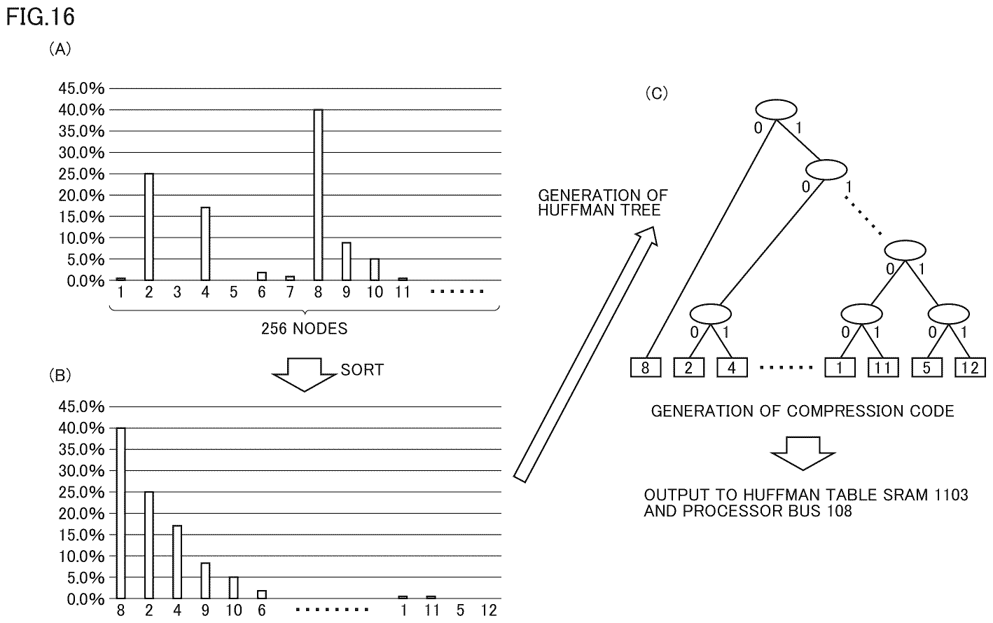

FIG. 16 is a schematic diagram showing a method of processing for Huffman table update in the Huffman table update phase.

Referring to FIG. 16(A), in the phase of generation of the compression code P times, a vote of +1 is given to a node corresponding to 256 types of signal data corresponding to eight bits each time of match with data provided from input data scanning unit 1101.

After completion of the phase of generation of the compression code P times, transition to the Huffman table update phase is made and the number of votes to each of 256 nodes is divided by the total number of votes L×P and converted to a probability of occurrence (%).

Referring to FIG. 16(B), the probability of occurrence is sorted in the descending order.

Referring to FIG. 16(C), a Huffman tree is generated based on the sorted data, and the compression code is generated for each node.

The generated compression code is written in Huffman table SRAM 1103 with original data corresponding to a corresponding node being defined as the address, and also provided to processor bus 108 for decompression of the compressed data on a side of the external system or the processor.

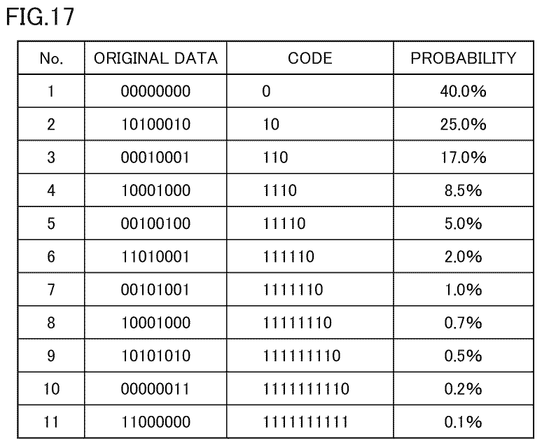

FIG. 17 shows a specific example of the Huffman table according to the third embodiment. A column on the left represents original 8-bit data and a column on the right represents a probability of appearance thereof. An example in which there are eleven types of 8-bit data in a prescribed block to be compressed is shown.

Referring to FIG. 17, a column in the center is a Huffman code acquired by calculation and derivation of a decision tree based on the probability of appearance of each piece of data. Codes of 0, 10, 110, . . . are allocated in the descending order of the probability of appearance.

A code compression ratio in using the Huffman table is expressed in an expression below, where S₁ (bit) represents a code size of i-th data and Pᵢ (%) represents probability of appearance of the i-th data. N represents the total number of types of 8-bit data that appears.

$$Compression Ratio = {\sum }_{n = 1}^{N} ( {S}_{i} {P}_{i} ) / 8 \qquad [ Expression 1 ]$$

The compression ratio in the case of the Huffman table shown in FIG. 17 is calculated as below, in accordance with the expression above.

(1×40.0%+2×25.0%+3×17.0%+4×8.5%+5×5.0%+6×2.0%+7×1.0%+8×0.7%+9×0.5%+10×0.2%+11×0.1%)/8=29.03%

As a result of calculation above, owing to code compression with the Huffman code, compression to an amount of code comparable to approximately 29% of original data can be achieved.

At most 256 addresses should only be secured as the address in Huffman table SRAM 1103 where the Huffman table is stored, and the Huffman table SRAM does not have to be arranged in an external memory and can be implemented in a small area as the SRAM on the LSI. Implementation on the SRAM contained in the LSI allows reference on a cycle basis. Therefore, as compared with implementation of the Huffman table in an external memory such as a DRAM, access latency is less and high-speed Huffman encoding can be achieved.

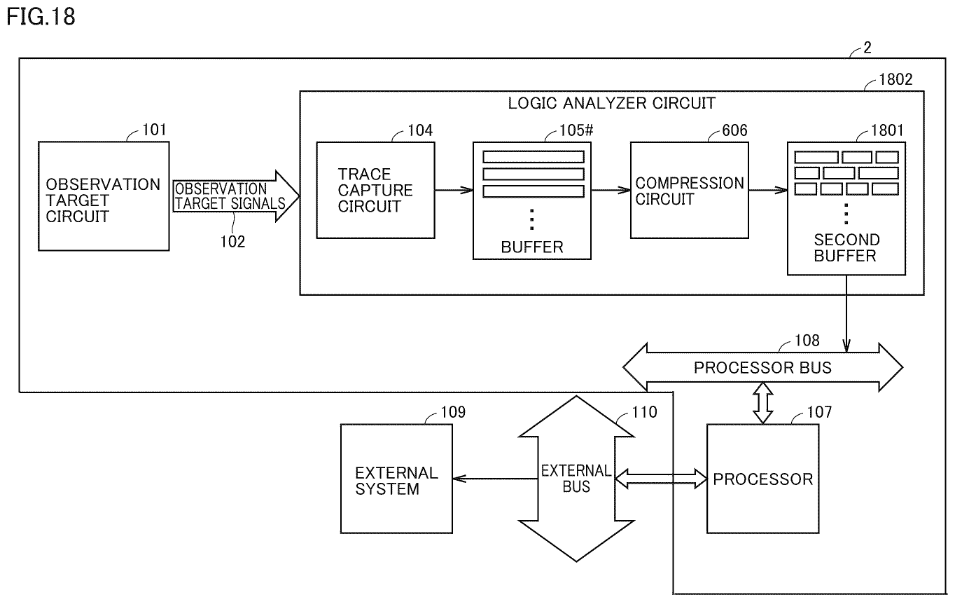

FIG. 18 is a diagram illustrating an integrated circuit according to another embodiment.

Referring to FIG. 18, an integrated circuit 2 is different from integrated circuit 1 #in addition of a second buffer 1801. Since the configuration is otherwise similar to the configuration described with reference to FIG. 7, detailed description will not be repeated.

A logic analyzer circuit 1802 further includes second buffer 1801 where compressed data is temporarily held, as compared with logic analyzer circuit 603 #.

Compression circuit 606 reads a data group (a plurality of signal data sets) stored in a buffer 105 #at earlier timing and has the compressed data stored in second buffer 1801 before issuance of a reading request from the processor. Therefore, as compared with logic analyzer circuit 603 #, the size of buffer 105 #can be smaller. In addition, since the compressed data is stored in second buffer 1801, the size of second buffer 1801 can also be smaller. A total of the sizes of buffer 105 #and second buffer 1801 can be smaller than the size of buffer 105 in logic analyzer circuit 603 #and the size of the memory to be included in the buffer can be more efficient.

The data compressed by compression circuit 606 may be decompressed in processor 107 contained in integrated circuit 2, converted to a general-purpose data format such as value change dump (VCD), and supplied to external system 109 through external bus 110. According to such a method, an effect of reduction in amount of transfer of data over the processor bus and supply of data in the general data format to the external system can be achieved.

The configurations exemplified as the embodiments described above are by way of example of the configuration in the present disclosure, and they can also be combined with another known technique or configured as being modified, for example, as being partially omitted, within the scope not departing from the gist of the present disclosure. Processing and configurations described in other embodiments may be adopted and carried out as appropriate in the embodiments described above.

It should be understood that the embodiments disclosed herein are illustrative and non-restrictive in every respect. The scope of the present disclosure is defined by the terms of the claims rather than the description above and is intended to include any modifications within the scope and meaning equivalent to the terms of the claims.

### REFERENCE SIGNS LIST

1 integrated circuit; 2 debugger; 5 display; 101 observation target circuit; 102 observation target signals; 103, 1802 logic analyzer circuit; 104 trace capture circuit; 105 buffer; 107 processor; 108 processor bus; 109 external system; 110 external bus; 201 signal data set; 202, 402 time stamp; 203 state change data; 606 compression circuit; 1101 input data scanning unit; 1102 original data SRAM; 1103 Huffman table SRAM; 1104 write data control unit; 1105 read data control unit; 1106 compressed data SRAM; 1107 data output control unit; 1108, 1109 selector; 1801 second buffer.

1. A logic analyzer circuit comprising:
a trace capture circuit to acquire N observation target signals from an observation target circuit when there is change in at least one of the N observation target signals; and
a buffer where signal data acquired by the trace capture circuit is stored, wherein
the signal data has
a time stamp of an M-bit width indicating time of acquisition, and
state change data of an N-bit width corresponding to respective values of the N observation target signals, and
the signal data is data in a binary format having a fixed length of (M+N) bits.

2. The logic analyzer circuit according to claim 1, further comprising a compression circuit to compress a plurality of pieces of the signal data stored in the buffer.

3. The logic analyzer circuit according to claim 2, wherein
the compression circuit divides the plurality of pieces of the signal data and compresses each piece of block data acquired by division.

4. The logic analyzer circuit according to claim 3, wherein
the compression circuit divides the plurality of pieces of the signal data into a plurality of patterns and compresses the plurality of pieces of the signal data, and selects compression patterns which achieves smallest compressed data size from among the plurality of patterns of compression.

5. The logic analyzer circuit according to claim 3, wherein
the compression circuit comprises
a first memory where signal data of each block acquired by division is stored,
an input data scanning unit to scan the signal data,
a Huffman table,
a write data control unit to initialize and update the Huffman table,
a read data control unit to read a compression code from the Huffman table based on the signal data,
a second memory where the compression code is stored, and
a data output control unit to output data in any one of the first memory and the second memory.

6. The logic analyzer circuit according to claim 5, wherein
the Huffman table is implemented by a static random access memory (SRAM).

7. The logic analyzer circuit according to claim 5, wherein the write data control unit creates statistical information such as a decision tree or a histogram acquired as a result of scanning of the signal data by the input data scanning unit and updates the Huffman table.

8. The logic analyzer circuit according to claim 5, wherein the read data control unit determines whether all of the signal data pf each block is 0 or not,
when all of the signal data of each block is 0, as a result of determination by the read data control unit, the data output control unit does not output any data, and
when not all of the signal data of each block is 0 as a result of determination by the read data control unit, the data output control unit calculates an amount of data of the compression code corresponding to each block and outputs data in any one of the first memory and the second memory based on a result of calculation.

9. The logic analyzer circuit according to claim 2, further comprising another buffer where signal data compressed by the compression circuit is stored.

10. An integrated circuit comprising:
the logic analyzer circuit according to claim 2; and a processor to decompress the compressed signal data provided from the compression circuit in the logic analyzer circuit.

11. An integrated circuit comprising:
an observation target circuit; a logic analyzer circuit to monitor a-observation target signals from the observation target circuit; and
a processor connected to the logic analyzer circuit, the processor transferring data to outside the integrated circuit, wherein
the logic analyzer circuit comprises:
a trace capture circuit to acquire N observation target signals from the observation target circuit when there is change in at least one of the N observation target signals, and
a buffer where signal data acquire by the trace capture circuit is stored,
the signal data has a time stamp of an M-bit width indicating time of acquisition, and
state change data of an N-bit width indicating values of the observation target signals, and
the signal data is in a binary format having a fixed length of (M+N) bits.

12. The integrated circuit according to claim 11, wherein
the integrated circuit further comprises a processor bus through which data is transmitted and received between the logic analyzer circuit and the processor.

13. An integrated circuit system comprising:
an integrated circuit;
an external bus for connection to the integrated circuit; and
an external apparatus to transmit and receive data to and from the integrated circuit through the external bus, wherein
the integrated circuit comprises
an observation target circuit,
a logic analyzer circuit to monitor a-observation target signal, from the observation target circuit, and
a processor connected to the logic analyzer circuit, the processor transferring data to the external apparatus through the external bus,
the logic analyzer circuit comprises
a trace capture circuit to acquire N observation target signals from the observation target circuit when there is change in at least one of the N observation target signals, and
a buffer where signal data acquired by the trace capture circuit is stored,
the signal data has
a time stamp of an M-bit width indicating time of acquisition, and
state change data of an N-bit width indicating values of the observation target signals, and
the signal data is in a binary format having a fixed length of (M+N) bits.

14. The logic analyzer circuit according to claim 1, further comprising
a compression circuit to compress a plurality of pieces of the signal data stored in the buffer, and wherein the compression circuit divides the plurality of pieces of the signal data, divides into a plurality of patterns, each piece of block data acquired by division and performs compression processing in parallel, and selects compression pattern which achieves smallest compressed data size from among results of the compression processing onto the plurality of patterns.

15. The logic analyzer circuit according to claim 14, wherein
the compression circuit comprises
a first memory where signal data of each block acquired by division is stored,
an input data scanning unit to scan the signal data,
a Huffman table,
a write data control unit to initialize and update the Huffman table,
a read data control unit to read a compression code from the Huffman table based on the signal data,
a second memory where the compression code is stored, and
a data output control unit to output data in any one of the first memory and the second memory, and
the first memory and the second memory are each configured to include a plurality of banks, and processing in a compression code generation stage and processing in a data output processing stage are performed with different banks being switched every prescribed cycles.
